(19) United States
(12) Patent Application Publication
(10) Pub. No.: US 2011/0290319 A1
(43) Pub. Date: Dec. 1, 2011

(54) THIN-FILM SOLAR CELL WITH CONDUCTOR TRACK ELECTRODE

(76) Inventors: Martin Melcher, Herzogenrath (DE); Wolfgang Andreas Nositschka, Aachen (DE); Didier Jousse, Taverny (FR)

(21) Appl. No.: 13/129,357

(22) PCT Filed: Nov. 25, 2009
(86) PCT No.: PCT/EP09/65829

§ 371 Date: Aug. 17, 2011

(30) Foreign Application Priority Data
Dec. 20, 2008 (DE) 102008064355.6

(51) Int. Cl. H01L 31/0216; H01L 31/18; B82Y 40/00; H01L 31/0224

(52) U.S. Cl. 136/256; 438/64; 977/842

(57) ABSTRACT

The invention relates to a method for producing a thin-film solar cell with a photoactive layer (100) that has, on the front side, an electrode (104) optically transparent in the range of visible light, wherein an electrically conductive network (110) of conductor tracks is applied on the rear side and/or the front side of the photoactive layer (100), which network, macroscopically seen, is transparent in the range of visible light.

The invention relates to a method for producing a thin-film solar cell as well as a thin-film solar cell.

Solar cells are devices that convert light energy into electrical energy using the photovoltaic effect. Solar cells contain a semiconductor material that is used to absorb photons and to generate electrons using the photovoltaic effect.

Nowadays, there is a great demand for solar cells since solar cells are used in many technical areas. For example, solar cells are used to operate stationary systems, as they are used, for example, in traffic monitoring and traffic flow regulation on freeways. A further example is automatic devices set up outdoors that are operated at least partially with solar energy.

Solar cells customary in the trade collect light from the front side and are opaque from the rear side since they are either applied to a nontransparent substrate or the rear electrode is not transparent. However, even with a solar cell oriented toward the sun, a non-negligible light output in the form of scattered light impinges on the rear side of the solar cell module with this scattering being caused both in the atmosphere and in the direct surroundings, such as by the subsoil, adjacent walls, etc. This light output in the form of scattered light assumes all the more significance if, instead of solar cells exactly oriented toward the sun, statically rigidly mounted solar cell modules are used, such as is frequently the case in the above-mentioned stationary systems. In this case, it will commonly occur that during most of most the period of insolation, the insolation does not optimally fall on the front side of the solar cells, as a result of which a valuable part of light output is not convertible into electric current. Similar problems occur when, for architectonic or structural reasons, optimum orientation toward the sun is not possible.

Solar cell modules functioning on both sides that can collect light from both the front side and from the rear side of the solar cells used offer one remedy for this.

For example, the patent U.S. 2007/0251570 discloses a thin-film solar cell that is transparent on both sides.

In contrast, the object of the invention is to create an improved method for producing a thin-film solar cell as well as an improved thin-film solar cell that is capable of collecting light both from the front side and the rear side and converting it into electrical energy.

The objects of the invention are in each case accomplished through the characteristics of the independent claims. Preferred embodiments of the invention are specified in the dependent claims.

The invention discloses a method for producing a thin-film solar cell with a photoactive layer that has, on the front side, an electrode optically transparent in the range of visible light, wherein an electrically conductive network of conductor tracks is applied on the rear side and/or the front side of the photoactive layer that, seen macroscopically, is optically transparent in the range of visible light. In the context of the invention, the range of visible light includes the wavelength range from 300 nm through 1300 nm. These limits result from the band gaps of the absorber material, such as silicon, and the inherent absorption of the glass material.

The network of conductor tracks (110) is preferably applied on the rear side of the photoactive layer (100). The conductor tracks of the network preferably contain particles of different sizes and geometries. Here, the term “particle” also includes aggregates, in particular, colloidal aggregates. Examples of aggregates are micelles and liquid crystalline structures.

According to another embodiment of the invention, in the method, an optically transparent plastic protective layer is applied on the network of conductor tracks. The material used for the plastic protective layer can comprise, for example, polyurethane (PU), ethylene vinyl acetate (EVA), or polyvinyl butyral (PVB). The additional application of the plastic protective layer has the advantage here that the network of conductor tracks is protected from external environmental influences or that the photoactive layer is encapsulated. Moreover, the use of such a plastic protective layer, for example, in the form of an EVA or PVB film, offers the capability of applying a glass surface on the rear side of the photoactive layer. The EVA or PVB film acquires an adhesion promoting effect and thus bonds the glass layer to the photoactive layer.

The method according to the invention has the advantage that, therewith, networks of conductor tracks can be produced simply and flexibly on the rear side of the photoactive layer. Thus, it is, for example, possible to apply the network directly on the rear side of the photoactive layer by a printing method, such as silk-screening, ink jet printing, aerosol jet printing, pulse jet printing, and offset printing, and/or flexography.

According to one embodiment of the invention, the method comprises the application of the electrically conductive network of conductor tracks on the rear side the photoactive layer. This includes the steps for application of a network of particles on the rear side and heating the network of particles to form the corresponding electrically conductive network of conductor tracks. The use of particles to form the conductor tracks has the advantage that the sintering temperature required for printing methods is reduced. Thus, it is, for example, possible, with a diameter distribution in the range below 100 nm, to reduce the sintering temperature all the way to 70° C. In this temperature range, the photoactive layer is not temperature sensitive since this layer is designed to withstand significantly higher temperatures, for example, under direct insolation.

Instead of the direct application of the network of conductor tracks on the rear side of the photoactive layer, it is also possible according to one embodiment of the invention to apply the electrically conductive network of conductor tracks on a plastic protective layer and/or an optically transparent surface layer. The layer thus prepared is then applied on the rear side of the photoactive layer. Depending on the material used for the plastic protective layer or depending on the method used, in which the electrically conductive network of conductor tracks is applied to the plastic protective layer, this can also be accomplished by application of a network of particles on the plastic protective layer followed by heating to form the electrically conductive network of conductor tracks. However, this requires that the plastic protective layer can withstand such heating of the network of particles without structural change.

According to one embodiment of the invention, the method further comprises the step of the application of an optically transparent surface layer on the plastic protective layer, wherein the plastic protective layer comprises an adhesion-promoting material to promote adhesion between the surface layer and the plastic protective layer and between the rear side of the photoactive layer and the plastic protective layer. For example, the optically transparent surface layer can be a glass surface that is “glued onto” the photoactive layer using the plastic protective layer. However, besides glass, plastic materials, preferably polyethylene terephthalate (PET) that are optically transparent in the range of visible light and have high mechanical hardness, but without having the weight and the rigid properties of conventional glass, can also be used as the transparent surface layer. This also provides the possibility of producing highly flexible solar cells that can be used, for example, through incorporation into textiles, as transportable energy sources.

According to another embodiment of the invention, the protective layer is a flexible film, with the application of the plastic protective layer and/or the optically transparent surface layer accomplished by laying and rolling onto the rear side of the photoactive layer. The use of a flexible film onto which the network of conductor tracks is applied has the advantage that production of solar cells, even, for example, of large area “endless” solar cells, is possible in continuous production methods. The plastic protective layer contains preferably polyurethane, ethylene vinyl acetate, and/or polyvinyl butyral.

According to one embodiment of the invention, the application of the electrically conductive network of conductor tracks on the plastic protective layer is accomplished through one or a plurality of the following methods such as silk-screening, inkjet printing, aerosol jet printing, pulse jet printing, heliogravure, offset printing, and/or flexography.

According to another embodiment of the invention, the application of the network of particles is accomplished through application of a dispersion, with the dispersion comprising the particles and a liquid. The liquid can be water and/or an organic solvent and/or a liquid plastic. The selection of the suitable liquid depends on various criteria, such as sinter temperature, aggregation behavior of the particles in the liquid as well as, in particular in the selection of liquid plastics as the liquid, the subsequent use of the cured plastic as protective conductive encapsulation of the particles. Also, surface-active substances, such as surfactants or amphiphilic polymers can be included.

According to one embodiment of the invention, the conductor tracks have a width between 1 μm and 1 mm, with the conductor tracks mutually separated by a distance of between 2 μm and 20 mm, preferably between 5 μm and 1 mm. However, in particular, the conductor tracks are dimensioned relative to their width and separation distance such that, with the least possible material outlay, an adequately high electrical conductivity for charge carrier transport can be ensured.

Another criterion for the arrangement of the conductor tracks is that the mutual separation distance of the conductor tracks be less than or equal to the migration length of the charge carrier in the photoactive layer. The advantageous width of the conductor tracks then results from this distance and the degree of coverage, which, for its part, determines the electrical resistance of the network. Thus, it is possible, for example, with a degree of coverage of 10%, to obtain a layer resistance of ca. 1 ohm per square when pastes containing silver particles are used as conductor track material. Here again, it is crucial that the size of the silver particles must be very small, e.g., clearly less than 1 μm, such that already with temperature treatments below 150° C., the desired conductivity is obtained. The particles are, preferably, metal particles, particularly preferably silver particles. Other possible metals are, for example, copper or aluminum.

Alternatively, the particles can also contain carbon particles. For example, the carbon particles can be carbon nanotubes and/or carbon black. The use of carbon nanotubes has the advantage that these have, because of their high aspect ratio of diameter and length, a low percolation limit relative to electrical conductivity. Thus, an extremely small quantity of carbon nanotubes suffices to nevertheless ensure high electrical conductivity of the conductor tracks formed therefrom.

“Carbon black” consists of small particles with a typical size range between 10 nm and 100 nm. In particular, with the use of carbon black, so-called “conductive carbon black”, which has particularly good electrical conductivity, can be used.

The particles form the conductor tracks preferably in the form of a composite material with a plastic. Such a plastic can be, for example, polyethylene (PE), or polymethyl methacrylate (PMMA), or polyaniline (PANI), or a combination thereof. Through the additional use of plastics in the conductor tracks, their mechanical stability is increased, for one thing. For another, through the use of conductive plastics such as polyaniline, for example, the electrical conductivity of the conductor tracks formed by particles is further increased. And third, the use of plastic in the conductor tracks serves to prevent a direct spatial contact between a photoactive layer and particles. Thus, even materials that, without encapsulation, would react chemically or electrochemically with the particles can be used as a photoactive layer. This increases the flexibility in the selection of materials that can be used in the photoactive layer.

According to another embodiment of the invention, the particles can, for example, have a diameter between 10 nm and 10 μm. However, preferably, the particles have a diameter between 100 nm and 1.50 μm, and particularly preferably, they have a diameter between 250 nm and 1 μm.

In a further aspect, the invention relates to a thin-film solar cell with a photoactive layer, wherein the front side has an electrode optically transparent in the range of visible light and the rear side has an electrically conductive network of conductor tracks that, seen macroscopically, is optically transparent in the range of visible light (300 nm to 1300 nm).

The conductor tracks preferably contain particles, particularly preferably with a diameter between 10 nm and 10 μm.

According to another embodiment of the invention, the rear side has, in addition to the conductor tracks, transparent conductive oxides. For example, these oxides can be indium tin oxide (ITO), aluminum tin oxide, antimony tin oxide, or fluorine tin oxide. These oxide layers can extensively cover the rear side of the photoactive layer, with the network of conductor tracks located either between the rear side of the photoactive layer and the oxide layer or between the oxide layer and a protective layer covering the oxide layer, for example, in the form of a plastic protective layer such as EVA. The use of an additional optically transparent conductive oxide layer has the advantage that a sheet electrode can be provided that has high electrical conductivity because of the additional network of conductor tracks. Because of the planar shape, the solar cell thus obtains high efficiency since charge carriers can be injected or skimmed off not only at the spatial positions of the conductor tracks but extensively over the entire rear side of the photoactive layer. The absorption of such a rear electrode of the photoactive material is, with a sheet resistance between 1 and 4 ohm per square, preferably between 5% and 20%.

In the following, embodiments of the invention are explained in greater detail with reference to the drawings. They depict:

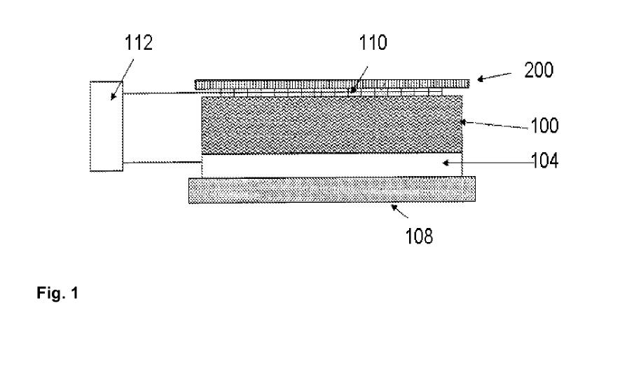

FIG. 1 a schematic view of a solar cell,

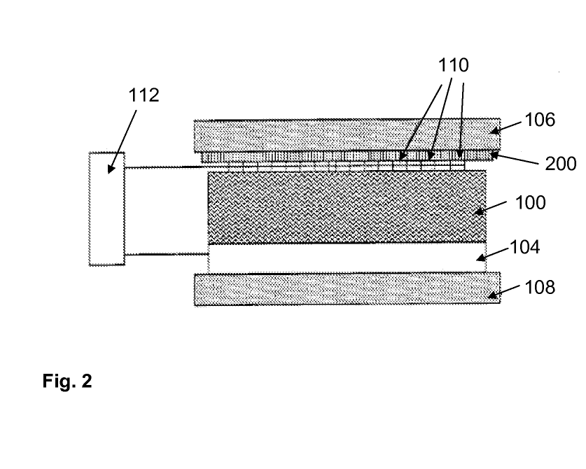

FIG. 2 a schematic view of another solar cell,

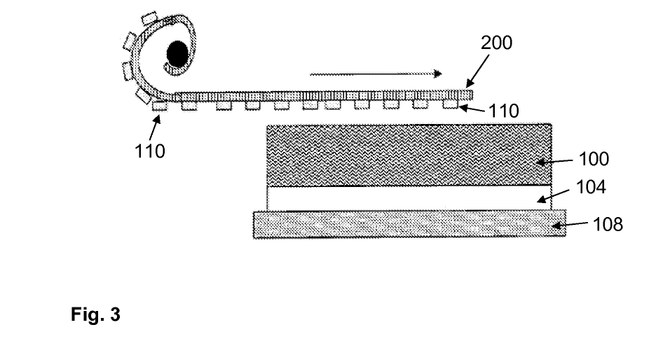

FIG. 3 a schematic view of a step of a method for producing a solar cell,

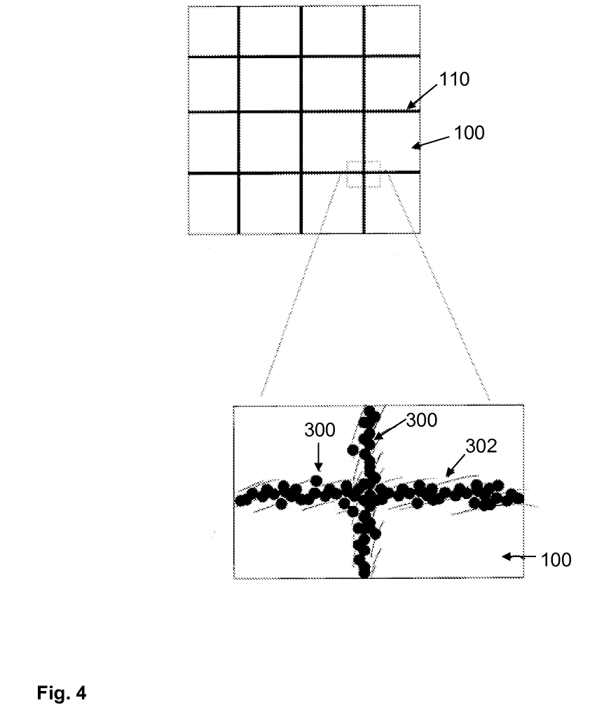

FIG. 4 a schematic view of a network of particles on a photoactive layer of a thin-film solar cell as well as a microscopic enlargement of the conductor track network,

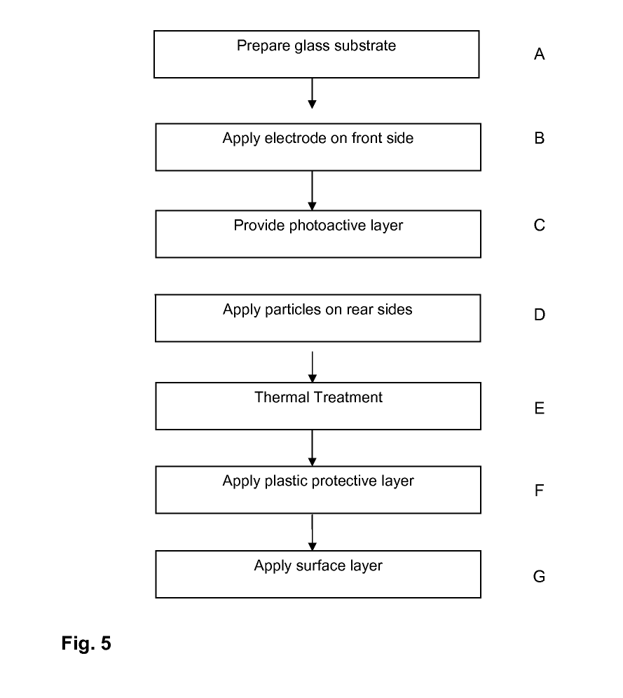

FIG. 5 a flowchart of a method for producing a thin-film solar cell.

In the following, elements similar to each other are labeled with the same reference characters.

FIG. 1 depicts a schematic view of a solar cell. The solar cell consists of a photoactive layer 100, with this photoactive layer preferably containing cadmium telluride (CdTe). Preferably, the solar cell depicted in FIG. 1 is a thin-film solar cell.

The solar cell of FIG. 1 has two electrodes: one electrode 104 on the front side of the photoactive layer 100 as well as one electrode 110 on the rear side of the photoactive layer 100. The electrode 110 is a network 110 of conductor tracks that are formed by particles, with the network 110 optically transparent in the range of visible light for incidence of light on the rear side of the photoactive layer 100.

For operation of the solar cell, the electrodes 104 and the network of conductor tracks 110 are coupled with an electrical load 112. Through incidence of light either through the electrode 104 onto the active layer 100 and/or through the network 110 onto the active layer 100, light energy is converted into electrical energy by charge carrier separation in the photoactive layer 100.

FIG. 1 further depicts two surface layers 200 and 108, with the plastic protective layer 200 arranged on the conductor tracks 110 and the surface layer 108 arranged on the electrode 104.

FIG. 2 depicts another schematic view of a solar cell. Unlike FIG. 1, FIG. 2 depicts a further surface layer 106. The surface layer 106 terminates the solar cell on the outside. The plastic protective layer 200 includes a plastic such as polyurethane (PU), ethylene vinyl acetate (EVA), or polyvinyl butyral (PVB). The plastic protective layer 200 can perform multiple functions. For example, such a plastic protective layer 200 has, when it is made of EVA or PVB film, an adhesion promoting effect.

Another purpose of the protective layer 200 can further consist in the sealing of the layer structure of the photoactive layer 100.

FIG. 3 depicts the photoactive layer 100 that has, on its front side, an optically transparent electrode 104. On it is disposed a surface layer 108, for example, a glass layer. According to one embodiment of the invention, the combination of the layers 100, 104, and 108 is, for example, provided for a production method. After that, in another operational step, the “rolling on” of a plastic protective layer, for example, an EVA film, onto which the electrically conductive network of conductor tracks 110 has already been applied, is performed. Thus, it is possible to produce solar cells in a continuous production method. For this, only the layers 100, 104, and 108 must be continuously provided such that, then, in a likewise continuous “rolling on” process, the electrode structure 110 is applied together with the EVA film 200 on the rear side of the photoactive layer 100.

FIG. 4 depicts an electrically conductive network of conductor tracks 110 on a photoactive layer 100. In the example of FIG. 4, the network thus formed forms a regular arrangement of conductor tracks that ensure good transparency because of the large separating distance between the individual conductor tracks. Thus, the network is substantially optically transparent in the range of visible light.

When the electrically conductive network of conductor tracks 110 is viewed enlarged, the particles 300 depicted in the enlarged representation in FIG. 4 become visible. The particles 300 are arranged relative to each other such that they form electrically conductive conductor tracks.

FIG. 4 moreover depicts a polymer 302, in which the particles 300 are embedded. The polymer 302 is, for example, an electrically conductive polymer that is filled with the particles up to a certain fill level, the percolation threshold. The reason for this is that at the percolation threshold, the electrical conductivity of the conductor tracks thus formed is already very high. Below the percolation threshold, the electrical conductivity is too low; and far above the percolation threshold, the electrical conductivity still rises only insignificantly, even with further addition of particles. Thus, through the suitable selection of a composite material consisting of particles 300 and filling material 302, an optimum composite material can be selected, which has, for one thing, high electrical conductivity and high mechanical stability and, also, high chemical inertness, for example.

FIG. 5 depicts a method for producing a solar cell. The method starts in Step A with the preparation of the glass substrate, such as cutting to size and washing. Then, in Step B, an electrode is applied on the front side of a glass substrate. In Step C, the photoactive layer is provided thereon. Step D follows, with the application of particles onto the surface of the photoactive layer, with the particles applied in the form of a network.

The optional Step E in the form of thermal treatment of the network of particles serves to form the electrically conductive network of conductor tracks. This is required in particular if they do not already have the required properties due to a simple, preferably fast, drying procedure. The heating can also serve as a curing process for a plastic used in forming the conductor tracks. Then, in Step F, a plastic protective layer, for example, an EVA film, is applied to the network of conductor tracks.

The printing paste should be designed for application of the particles on the rear side such that it preferably achieves the desired conductivity without heating above 150°. This is true in particular for printing techniques such as silk-screening, for example. Thus, temperature stability is ensured particularly with the use of a CdTe-layer structure of the photoactive layer.

The method is concluded in Step G with the application of a surface layer on the electrode of the front side or the EVA film on the rear side of the photoactive layer. These surface layers can, for example, be plastic protective layers or glass layers between which the solar cell module created is packed.

### LIST OF REFERENCE CHARACTERS

100 photoactive layer
104 electrode
106 surface layer
108 surface layer
110 network
112 electrical load
200 plastic protective layer
300 particle
302 polymer

1. (canceled)

2. The method according to claim 13, wherein the network of conductor tracks is applied on the rear side of the photoactive layer.

3. The method according to claim 13, wherein the applying of the electrically conductive network of conductor tracks on the rear side of the photoactive layer comprises:
applying a network of particles on the rear side, and
heating the network of particles to form the electrically conductive network of conductor tracks.

4. The method according to claim 13, wherein the applying of the electrically conductive network of conductor tracks on the rear side of the photoactive layer comprises:
applying the electrically conductive network of conductor tracks on a surface layer optically transparent in the range of visible light and/or a plastic protective layer, and
applying the surface layer and/or the plastic protective layer with the electrically conducting network of conductor tracks on the rear side of the photoactive layer.

5. The method according to claim 4, wherein the plastic protective layer and/or optically transparent surface layer is a flexible film, wherein the plastic protective layer and/or the optically transparent surface layer is applied by rolling onto the rear side of the photoactive layer.

6. The method according to claim 4, wherein the plastic protective layer contains polyurethane, ethyl vinyl acetate, or polyvinyl butyral.

7. The method according to claim 13, wherein the electrically conductive network of conductor tracks is applied by one or more methods wherein each method is selected from the group consisting of a silk-screening method, an inkjet printing method, an aerosol jet printing method, a pulse jet printing method, a heliogravure, an offset printing method, and a flexography method.

8. The method according to claim 13, wherein:
the network of conductive tracks containing particles is applied by application of a dispersion,
the dispersion comprises the particles and a liquid, and
the liquid is water and/or an organic solvent and/or a liquid plastic.

9. The method according to claim 13, wherein the particles, as part of a composite material, form the conductor tracks.

10. The method according to claim 13, wherein the particles have a diameter between 10 nm and 10 μm.

11. A thin-film solar cell with a photoactive layer, wherein a front side of the photoactive layer has an electrode optically transparent in the range of visible light and a rear side has an electrically conductive network of conductor tracks, wherein the electrically conductive network is optically transparent in the range of visible light and the conductor tracks contain particles.

12. The solar cell according to claim 11, wherein the rear side has transparent conductive oxides in addition to the conductor tracks.

13. A method for producing a thin-film solar cell with a photoactive layer, the method comprising:
producing an electrode on a front side of the thin-film solar cell, the electrode being optically transparent in the range of visible light, and
applying an electrically conductive network of conductor tracks on a rear side and/or front side of the photoactive layer, wherein:
the network is optically transparent in the range of visible light,
the conductor tracks contain particles, wherein the particles are metal particles and/or carbon particles,
the conductor tracks have a width between 1 μm and 1 mm, and
the conductor tracks are mutually separated by a distance of between 2 μm and 20 mm.

14. The method according to claim 13, wherein each particle is selected from the group consisting of silver particle, carbon nanotube particle, carbon black particle, and conductive carbon black particle.

15. The method according to claim 9, wherein the composite material further comprises a plastic.

16. The method according to claim 15, wherein the plastic comprises one or more plastic materials and each plastic material is selected from the group consisting of polyethylene, polymethyl methacrylate, and polyaniline.

17. The method according to claim 10, wherein the particles have a diameter between 100 nm and 1.50 μm.

18. The method according to claim 10, wherein the particles have a diameter between 250 nm and 1 μm.

19. The method according to claim 3, wherein the applying of the electrically conductive network of conductor tracks on the rear side of the photoactive layer comprises:
applying the electrically conductive network of conductor tracks on a surface layer optically transparent in the range of visible light and/or a plastic protective layer, and
applying the surface layer and/or the plastic protective layer with the electrically conductive network of conductor tracks on the rear side of the photoactive layer.

20. The method according to claim 5, wherein the plastic protective layer comprises polyurethane, ethyl vinyl acetate, or polyvinyl butyral.
